(19) United States
(12) Patent Application Publication
(10) Pub. No.: US 2023/0375622 A1
(43) Pub. Date: Nov. 23, 2023

(54) KALMAN FILTER-BASED SOC ESTIMATION METHOD, SYSTEM, MEDIUM AND ELECTRONIC DEVICE

(71) Applicant: SHANGHAI MAKESENS ENERGY STORAGE TECHNOLOGY CO., LTD., Shanghai (CN)

(72) Inventors: Guopeng Zhou, Shanghai (CN); Peng Ding, Shanghai (CN); Enhai Zhao, Shanghai (CN); Xiao Yan, Shanghai (CN); Xiaohua Chen, Shanghai (CN); Pei Song, Shanghai (CN); Weikun Wu, Shanghai (CN); Danfei Gu, Shanghai (CN); Pingchao Hao, Shanghai (CN)

(21) Appl. No.: 18/143,112

(22) Filed: May 4, 2023

(30) Foreign Application Priority Data
May 20, 2022 (CN) 202210558240.8

(51) Int. Cl. G01R 31/36; G01R 31/367; G01R 31/3842

(52) U.S. Cl. CPC G01R 31/3648; G01R 31/367; G01R 31/3842

(57) ABSTRACT

The invention provides a Kalman filter-based SOC estimation method, system and medium, and an electronic device therewith. The method includes extracting a cell voltage of a battery pack to calculate a terminal voltage, and matching the terminal voltage in a preset lookup table to obtain an initial value of the SOC; calculating an initial capacity of the battery pack based on the initial value of the SOC, and calculating a state value of the SOC and an observed value of the SOC in an interval period based on the initial capacity; calculating a Kalman gain based on the state value of the SOC and the observed value of the SOC, and updating an estimated value of the SOC based on the Kalman gain.

### CROSS-REFERENCE TO RELATED PATENT APPLICATION

This application claims priority to and the benefit of Chinese Patent Application No. 202210558240.8, filed May 20, 2022, which are incorporated herein in their entireties by reference.

### FIELD OF THE INVENTION

The invention relates to the field of battery managements, and more particularly to a Kalman filter-based SOC estimation method, system, medium and electronic device.

### BACKGROUND OF THE INVENTION

More and more people choose the electric vehicles for transportation. Lithium batteries are used as the energy source of the electric vehicles, and SOC is one of the most important parameters in energy managements. The SOC refers to a state of charge of a battery, which is used to describe the remaining amount of energy available in the battery at a specific point in time. Only can an accurate SOC estimation make a reasonable energy allocation, thereby more effectively using the remaining amount of energy of the battery and correctly predicting the remaining mileage of which the electric vehicle can run.

However, the lithium batteries are a closed and complex nonlinear system, and the external environment and internal parameters change randomly, which makes the mathematical model of the system inaccurate and generates errors. Therefore, it is necessary to improve the accuracy and anti-interference ability of the battery state of charge estimation robustness.

Most of the existing methods for predicting the SOC of lithium batteries cannot estimate the SOC value in real time, and do not take into account the influence of temperature on the SOC estimation. All the technologies currently used need to upload the battery parameters of electric vehicles to the cloud, and then estimate the parameters online. It may be difficult to apply to certain electric vehicles. In addition, the online estimation cannot accurately predict the SOC under non-Gaussian white noises.

Therefore, a heretofore unaddressed need exists in the art to address the aforementioned deficiencies and inadequacies.

### SUMMARY OF THE INVENTION

In view of the above-noted shortcomings of the prior art, one of the objectives of this invention is to provide a Kalman filter-based SOC estimation method, system, medium and electronic device for solving the problems of battery capacity detection of electric vehicles in the prior art.

In order to achieve the above objective and other related objectives, one aspect of the invention provides a Kalman filter based method for estimating the SOC. The method includes: extracting a cell voltage of a battery pack to calculate a terminal voltage, and matching the terminal voltage in a preset lookup table to obtain an initial value of the SOC; calculating an initial capacity of the battery pack based on the initial value of the SOC, and calculating a state value of the SOC and an observed value of the SOC in an interval period based on the initial capacity; and calculating a Kalman gain based on the state value of the SOC and the observed value of the SOC, and updating an estimated value of the SOC based on the Kalman gain.

In one embodiment, the cell voltage of the battery pack is extracted to calculate the terminal voltage, and the terminal voltage is matched in the preset lookup table to obtain the initial value of the SOC, which specifically includes: identifying a present state of charging or discharging of the battery pack based on a detected current.

When the battery pack is in the charging state, a first voltage is extracted as the cell voltage of the battery pack, the terminal voltage is calculated based on the first voltage, and the terminal voltage compared with the charging voltage in the lookup table to obtain the corresponding initial value of the SOC.

When the battery pack is in the discharging state, a second voltage is extracted as the cell voltage of the battery pack, the terminal voltage is calculated based on the second voltage, and the terminal voltage is compared with the discharge voltage in the lookup table to obtain the corresponding initial value of the SOC.

In one embodiment, the calculation of the initial capacity of the battery based on the initial value of the SOC, and the calculation of the state value of the SOC and the observed value of the SOC in the interval period based on the initial capacity specifically include: calculating the initial capacity of the battery pack in combination with a rated capacity of the battery pack and a present temperature of the battery pack; extracting a change value of the initial capacity within the interval period, and calculating the state value of the SOC in combination with the rated capacity and the temperature; and extracting the cell voltage and current at the present moment within the interval period to obtain a second equivalent resistance, and matching in the look-up table to obtain the observed value of the SOC.

In one embodiment, the lookup table is generated by extracting a charge voltage and a charge current when an electric vehicle is in its first charge, and a discharge voltage and a discharge current when the electric vehicle is its first discharge; obtaining a first equivalent resistance based on the charging voltage, the discharging voltage, the charging current, and the discharging current; and generating the lookup table by using the first equivalent resistance, the charge voltage and the discharge voltage as table elements.

In one embodiment, the method further includes updating the Kalman gain in each interval period.

In one embodiment, the method further includes updating the lookup table based on the updated estimated value of the SOC.

To achieve the above objective and other related objectives, another aspect of the invention provides a system for SOC estimation based on a Kalman filter. The system comprises:
an extraction module, configured to extract a cell voltage of a battery pack to calculate a terminal voltage, and match the terminal voltage in a preset lookup table to obtain an initial value of the SOC;
a calculation module, configured to calculate an initial capacity of the battery pack based on the initial value of the SOC, and calculate a state value of the SOC and an observed value of the SOC in an interval period based on the initial capacity; and
an updating module, configured to calculate a Kalman gain based on the state value of the SOC and the observed value of the SOC, and update an estimated value of the SOC based on the Kalman gain.

To achieve the above objective and other related objectives, one aspect of the invention provides a non-transitory tangible computer-readable storage medium storing a computer program which, when executed by one or more processors, carries out the method the program is executed by a processor, the Kalman filter-based SOC estimation method as disclosed above.

To achieve the above objective and other related objectives, another aspect of the invention provides an electronic device, which includes: a processor and a memory; wherein the memory is used to store a computer program, and the processor is used to execute the computer program stored in the memory to cause the electronic device to execute the Kalman filter-based SOC estimation method.

As disclosed above, the Kalman filter-based SOC estimation method, system, medium and electronic device according to embodiments of the invention can be used to integrate the detection parameters and the SOC estimation algorithm together on the chip, and estimate the SOC in real time. It can accurately identify the SOC of the electric vehicle battery, predict the state of the battery and help drivers determine whether it is enough to ride so as to prevent electric vehicles from power failure when driving and improve the driving safety. In addition, by taking temperature effects into account, the SOC estimation is adaptively adjusted according to temperature changes to ensure that the estimation results at high and low temperatures still have high accuracy.

### BRIEF DESCRIPTION OF THE DRAWINGS

The accompanying drawings illustrate one or more embodiments of the invention and, together with the written description, serve to explain the principles of the invention. The same reference numbers may be used throughout the drawings to refer to the same or like elements in the embodiments.

FIG. 1 shows schematically a flow chart of a Kalman filter-based method for SOC estimation according to one embodiment of the invention.

FIG. 2 shows schematically a flow chart of a Kalman filter-based method for SOC estimation according to one embodiment of the invention.

FIG. 3 shows schematically a flow chart of a Kalman filter-based method for SOC estimation according to one embodiment of the invention.

FIG. 4 shows schematically a flow chart of a Kalman filter-based method for SOC estimation according to one embodiment of the invention.

FIG. 5 shows results of the SOC estimation by the Kalman filter-based method for SOC estimation according to one embodiment of the invention.

FIG. 6 is a schematically structural diagram of a Kalman filter based SOC estimation system according to one embodiment of the invention.

FIG. 7 is a schematically structural diagram of an electronic device according to one embodiment of the invention.

### DETAILED DESCRIPTION OF THE INVENTION

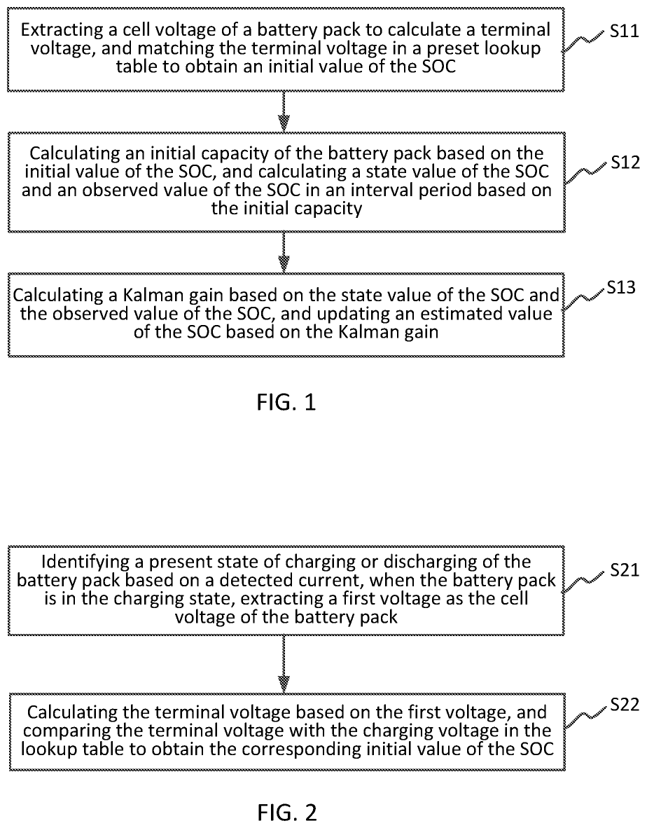

Embodiments of the invention are described below through specific examples in conjunction with the accompanying drawings in FIGS. 1-7, and those skilled in the art can easily understand other advantages and effects of the invention from the content disclosed in this specification. The invention can also be implemented or applied through other different specific implementations, and various modifications or changes can be made to the details in this specification based on different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. They do not represent the actual structure of the product. Dimensional drawing, the type, quantity and proportion of each component can be changed arbitrarily in its actual implementations. More complicate component layouts may also become apparent in view of the drawings, the specification, and the following claims.

Referring to FIG. 1, a Kalman filter-based method for estimation of a state of charge (SOC) of a battery pack is shown according to one embodiment of the invention. In the exemplary embodiment, the method comprises the following steps:

At step S11, extracting a cell voltage of a battery pack to calculate a terminal voltage, and matching the terminal voltage in a preset lookup table to obtain an initial value of the SOC.

At step S12, calculating an initial capacity of the battery pack based on the initial value of the SOC, and calculating a state value of the SOC and an observed value of the SOC in an interval period based on the initial capacity.

At step S13, calculating a Kalman gain based on the state value of the SOC and the observed value of the SOC, and updating an estimated value of the SOC based on the Kalman gain.

It should be noted that, as shown in FIG. 4, the lookup table is generated specifically by the following steps: at step S41, extracting a charge voltage and a charge current when an electric vehicle is in its first charge, and a discharge voltage and a discharge current when the electric vehicle is its first discharge; at step S42, obtaining a first equivalent resistance based on the charging voltage, the discharging voltage, the charging current, and the discharging current; and at step S43, generating the lookup table by using the first equivalent resistance, the charge voltage and the discharge voltage as table elements. According to embodiments of the invention, the lookup table is used because of practicality and feasibility of the SOC estimation based on chips/device, which includes a little device memory, yet performs and retains high accuracy, and can achieve real-time response, without compromising accuracy and precision.

Specifically, for the first charge and discharge of the electric vehicle, extract the charging voltage U_{charge}, the discharge voltage U_{discharge}, the charging current I_{charge}, and the discharge current I_{discharge} are extracted to obtain the first equivalent resistance R₀, wherein the first equivalent resistance R₀=(U_{charge}−U_{discharge})/(I_{charge}−I_{discharge}). Referring to Table 1, which is a non-limited, exemplary example of the lookup table. It should be note that in actual applications, the parameter values are not limited to that in the table.

TABLE 1
A lookup table

| R₀ | U_{discharge} | U_{charge} | SOC |
|---|---|---|---|
| 180 | 2960 | 3090 | 0 |
| 150 | 3030 | 3140 | 5 |
| 60 | 3090 | 3180 | 10 |
| 100 | 3140 | 3200 | 15 |
| 110 | 3180 | 3220 | 20 |
| 95 | 3200 | 3240 | 25 |
| 70 | 3220 | 3250 | 30 |
| 70 | 3240 | 3270 | 35 |
| 80 | 3250 | 3280 | 40 |
| 80 | 3270 | 3290 | 45 |
| 85 | 3280 | 3300 | 50 |
| 85 | 3290 | 3305 | 55 |
| 90 | 3300 | 3310 | 60 |
| 90 | 3305 | 3315 | 65 |
| 90 | 3310 | 3330 | 70 |
| 80 | 3315 | 3340 | 75 |
| 80 | 3330 | 3380 | 80 |
| 70 | 3340 | 3480 | 85 |
| 75 | 3360 | 3510 | 90 |
| 79 | 3380 | 3530 | 95 |
| 87 | 3400 | 3580 | 100 |

Further, as shown in FIG. 2, the step of extracting the cell voltage of the battery pack to calculate the terminal voltage, and matching the terminal voltage in the preset lookup table to obtain the initial value of the SOC comprises the following steps:

At step S21, identifying a present state of charging or discharging of the battery pack based on a detected current, wherein, when the battery pack is in the charging state, extracting a first voltage as the cell voltage of the battery pack.

At step S22, calculating the terminal voltage based on the first voltage, and comparing the terminal voltage with the charging voltage in the lookup table to obtain the corresponding initial value of the SOC.

Specifically, the present current I, the present voltage U′, and the present temperature T can be detected by the detection chip. Based on the detected current, it can be determined whether the battery pack of the electric vehicle is charging or discharging at this time. At the initial use, the electric vehicle is in the charging state, the present voltage U′ is the first voltage, the terminal voltage U₁=U′−|I|*R₀ is calculated, and then the terminal voltage U₁ is compared with the voltage value corresponding to the charge voltage U_{charge} of the lookup table to obtain the SOC corresponding to the battery pack under the initial condition. The maximum voltage value of the present voltage U′ is used for calculation and comparison when charging the electric vehicle.

It should be noted that the initial capacity Cap of the battery can be calculated by combining the rated capacity R_{Cap} of the battery and the present temperature T, where the initial capacity Cap=soc*R_{Cap}*kᵣ, where kᵣ is the temperature coefficient, showing the ratio of the battery capacity at different temperatures T to the battery capacity at 25° C. Specifically:

$${k}_{r} = \{ \begin{matrix}1 , & when T \geq 25 ° C . \\ a ⋆ T + b , & when T < 25 ° C .\end{matrix}$$

wherein the temperature coefficient kᵣ is in a range of 0-1, and a and b are parameters that are extracted from the temperature-capacity relationship curve of a certain type of batteries, such as a lithium iron phosphate battery, and the extraction steps are not repeated in this embodiment.

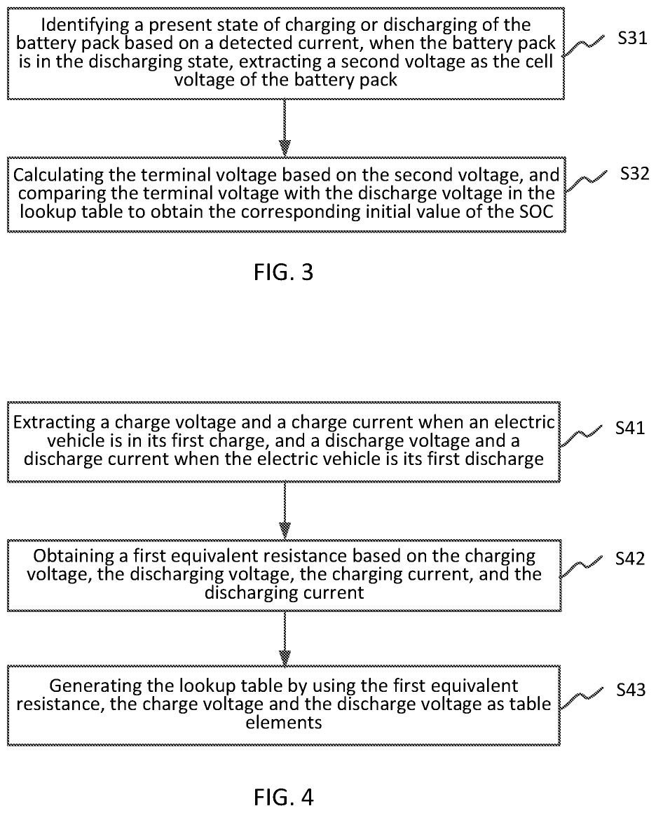

In addition, as shown in FIG. 3, the step of extracting the cell voltage of the battery pack to calculate the terminal voltage, and matching the terminal voltage in the preset lookup table to obtain the initial value of the SOC also includes the following steps:

At step S31, when the battery pack is in the discharging state, extracting a second voltage as the cell voltage of the battery pack.

At step S32: calculating the terminal voltage based on the second voltage, and comparing the terminal voltage with the discharge voltage in the lookup table to obtain the corresponding initial value of the SOC.

Specifically, when the battery pack is in the discharge state, the present voltage U″ during discharging is the second voltage, and the terminal voltage U₁=U″−|I|*R₀ is calculated, and then terminal voltage U₁ is compared with the voltage value corresponding to the discharge voltage U_{discharge} in the lookup table to obtain the SOC corresponding to the battery pack in the discharge state. The minimum voltage value of the present voltage U″ is used for calculation and comparison when discharging the electric vehicle.

Further, the initial capacity of the battery pack is calculated based on the initial value of the SOC, and the state value of the SOC and the observed value of the SOC are calculated in the interval period based on the initial capacity. Specifically, the initial capacity of the battery pack is calculated in combination with a rated capacity of the battery pack and a present temperature of the battery pack; a change value of the initial capacity within the interval period is extracted, and the state value of the SOC is calculated in combination with the rated capacity and the temperature; and the cell voltage and current at the present moment within the interval period are extracted to obtain a second equivalent resistance, and matched in the look-up table to obtain the observed value of the SOC. In certain embodiments, the cell voltage (namely the first/second voltage) is compared with the voltage in the lookup table to get the equivalent resistance; then the equivalent resistance and the first/second voltage are used to calculate the terminal voltage. The observed value of the SOC is obtained through comparing the calculated terminal voltage with the voltage in the lookup table.

In some embodiments, the chip (e.g., control unit) of the electric vehicle uploads data once per second, and calculates the change value ∇Cap of the battery capacity once every second. ∇Cap=I*∇t is obtained by Using the ampere-hour integration method. When the data uploaded by the chip is accumulated in one minute, “1 min”, the present capacity Capₖ is the sum of the initial capacity of this “1 min” and the change value ∇Cap of the capacity within the “1 min”. The state value of the SOC, Sôcₖ⁻, at the present moment can be calculated by combining the battery rated capacity R_{Cap} and the temperature T in the formula of

Capₖ=Capₖ₋₁+∇Capₖ

Sôcₖ=Capₖ/(R_{cap}*kᵣ);

wherein the battery capacity Capₖ₋₁=SOCₖ₋₁*R_{Cap}*kᵣ at the previous moment (i.e., in this embodiment, the previous “1 min”). It should be noted that the interval “1 min” is only an example of the present invention, and in actual applications, the interval is not limited to “1 min”, and any other intervals can also be utilized to practice the invention.

Further, by looking up the lookup table the corresponding observed value of the SOC, Sôc_{observed}, is obtained. The second equivalent resistance R₀′ is obtained according to the current and voltage at the present moment, and then the terminal voltage U₁ at the present moment is calculated based on the second equivalent resistance R₀′. The corresponding terminal voltage U₁ is compared with the voltage value of the charging voltage U_{charge} or discharge voltage U_{discharge} in the lookup table to obtain the current observed value of the SOC Sôc_{observed}.

In some embodiments, the method further includes updating the Kalman gain in each interval period.

In some embodiments, in the Kalman filter estimation, the Kalman gain Kₖ is calculated based on the error covariance R between the observed value of the SOC and the actual value of the SOC and the error covariance Q between the state value of the SOC and the actual value of the SOC with the formulas of:

Kₖ=(Pₖ₋₁+Q)/(Pₖ₋₁+Q+R);

Pₖ=(1−Kₖ)*(Pₖ₋₁+Q)

Pₖ₋₁ is the error variance between the estimated value of the SOC and the actual value of the SOC at the last moment (i.e., in this embodiment, the previous “1 min”). The updated SOC at this moment is Sôcₖ=Sôcₖ⁻+Kₖ (Sôc_{observed}−Sôcₖ⁻). The estimated value of the SOC at this moment is Sôcₖ. As the charge and discharge processes proceed, the state value of the SOC Sôcₖ⁻ is more accurate, and adaptively adjusting Q to be smaller and R to be larger are needed. When the charge and discharge process is proximate to the charge and discharge cutoff voltages, the observed value of the SOC Sôc_{observed} is more accurate, and adaptively adjusting Q to be larger and R to be smaller are needed. Preferably, the updated Q and R are automatically used to calculate the Kalman gain K at the next moment.

In one embodiment, when Pₖ₋₁=1, Q=1 and R=10, the Kalman gain Kₖ=0.167 is obtained, and the corresponding Pₖ=(1−0.167)*(1+1)=1.667. The Kalman gain Kₖ at the next moment is calculated using the updated Pₖ, Q and R. After a period of iteration, Pₖ and Kₖ will tend to “0”, which indicates that the state value of the SOC is very close to the actual value of the SOC. And at this moment, whether Kₖ is iterated or not does not affect the subsequent calculation results. Preferably, Q and R can be regarded as the variance of the normal distribution, which is the distribution width of the normal distribution, indicating the distribution probability of the difference from the actual value.

In one embodiment, the difference between the estimated value of the SOC Sôcₖ and the observed value of the SOC Sôc_{observed} at the present moment k is defined as the error dsoc, and it is also similar for the previous moment (i.e., k−1 time), the formulas are:

dsocₖ₋₁=Sôcₖ₋₁−Sôc_{observed(k-1)};

dsocₖ=Sôcₖ−Sôc_{observed(k)}

If it is determined that the error/deviation between the observation quantity Sôc_{observed} and the actual value of the SOC is large, then the R value is increased adaptively. When the state value of the SOC Sôcₖ⁻ is more accurate, it is necessary to adaptively adjust Q to be smaller and R to be larger (alternatively, Q is kept unchanged, and R is greatly increased).

In one embodiment, the method further includes updating the lookup table based on the updated estimated value of the SOC.

In some embodiments, it is determined whether the present estimated value Sôcₖ of the SOC is consistent with the SOC value corresponding to the lookup table. If they are consistent, the lookup table needs to be updated. If the charge state is determined at this moment, U_{charge} and R₀ in the lookup table are updated. If the discharge state is determined at this moment, U_{discharge} and R₀ in the lookup table are updated, which satisfy the formula of:

$$\begin{matrix}{U}_{charge} = {U}_{max} - \vert I \vert ⋆ {R}_{0} ; \\ {U}_{discharge} = {U}_{min} - \vert I \vert ⋆ {R}_{0} ; \\ {R}_{0} = \frac{{U}_{charge} - {U}_{discharge}}{{I}_{charge} - {I}_{discharge}} ;\end{matrix}$$

wherein Uₘₐₓ is the maximum value of the cell voltage in the detected and uploaded battery pack, Uₘᵢₙ is the minimum value of the cell voltage in the detected and uploaded battery pack, I_{charge} is positive when charging, and I_{discharge} is negative when discharging. After the values in the lookup table are updated, it will be automatically used for the calculation of the observed value of the SOC Sôc_{observed} at the next moment.

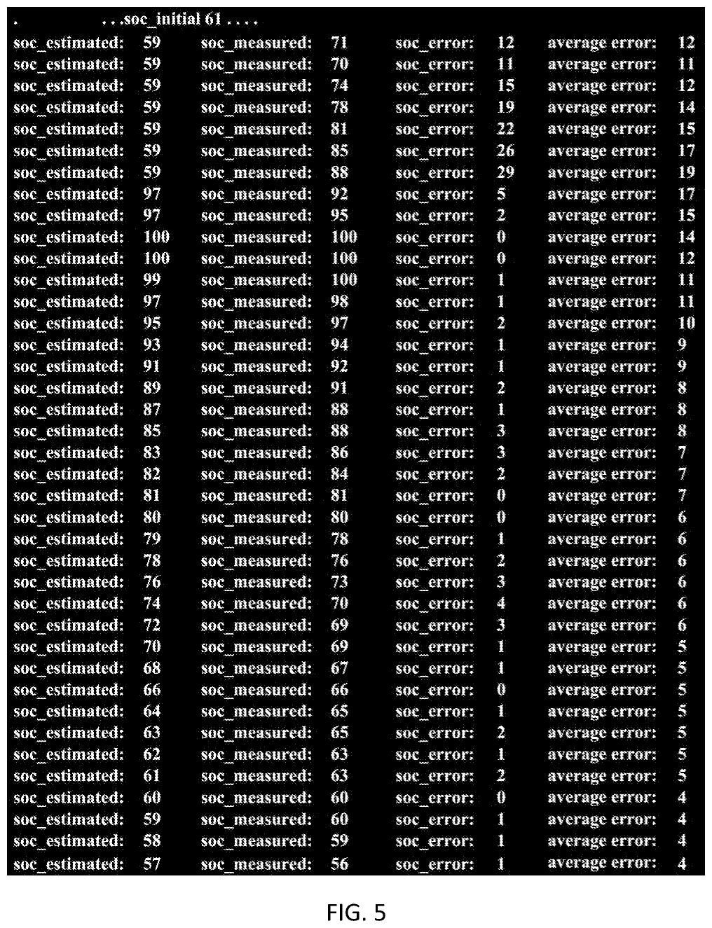

FIG. 5 shows the results of the SOC estimated by the Kalman filter-based method performed in a battery pack according to one embodiment of the invention, wherein the error is within “5%”, soc_estimated is the estimated value of the SOC estimated by the Kalman filter algorithm, soc_measured is the actual measured value in the experiment with a chip such as GigaDevice32E230C (GigaDevice Semiconductor Inc., Beijing, China), soc_error is the error between the difference between the estimated value and the actual value of the SOC, and the average error is the average values of the error at the present moment and the errors at all previous moments. As shown in FIG. 5, the initial estimation error is relatively large, because the Kalman filter has not been used for SOC estimation at this moment, and the observed value of the SOC Sôc_{observed} is obtained by looking up the lookup table. As the charge and discharge processes proceed, the estimated value of the SOC is more accurate at the later moments.

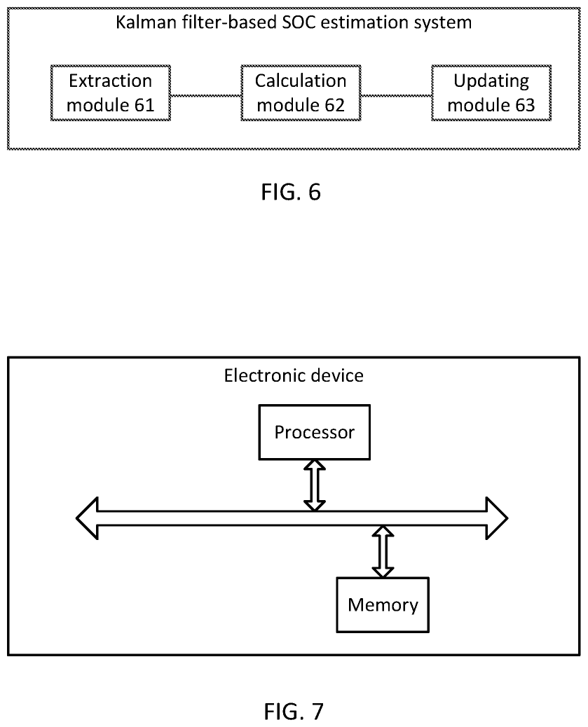

Referring to FIG. 6, a system for estimating the SOC based on Kalman filter is schematically shown according to one embodiment of the invention. The system comprises an extraction module 61, a calculation module 62 and an updating module 63.

The extraction module 61 is configured to extract a cell voltage of a battery pack to calculate a terminal voltage, and match the terminal voltage in a preset lookup table to obtain an initial value of the SOC.

The calculation module 62 is configured to calculate an initial capacity of the battery pack based on the initial value of the SOC, and calculate a state value of the SOC and an observed value of the SOC in an interval period based on the initial capacity.

The updating module 63 is configured to calculate a Kalman gain based on the state value of the SOC and the observed value of the SOC, and update an estimated value of the SOC based on the Kalman gain.

Since the specific implementation of this embodiment corresponds to the aforementioned method embodiment, the same details will not be repeated here. Those skilled in the art should also understand that the division of the modules in the embodiment shown in FIG. 6 is according to logical functions, and all the modules can be fully or partly integrated into one or more physical entities during actual implementation, and these modules can be implemented in the form of calling by processing elements in software, or in the form of hardware, or some modules are realized by calling software from processing elements, and the other modules are realized by hardware.

In another aspect, the invention also provides a non-transitory tangible computer-readable storage medium on which a computer program is stored, the computer program, when executed by one or more processors, implementing the Kalman filter-based method for the SOC estimation.

Those of ordinary skill in the art will understand that all or part of the steps for implementing the above method embodiments may be performed by hardware associated with a computer program. The aforementioned computer program may be stored in a computer readable storage medium. When executed, the computer program performs steps comprising the method embodiments described above; and the aforementioned computer-readable storage media comprise: various computer storage media that can store program codes, such as ROM, RAM, magnetic or optical disks.

Referring to FIG. 7, an electronic device is shown according to one embodiment of the invention. Specifically, the electronic device at least includes: a memory and a processor connected by one or more buses. The memory is used to store a computer program, and the processor is used to execute the computer program stored in the memory, as so to implement all or part of the steps in the foregoing method embodiments.

In summary, the invention integrates the detection parameters and the SOC estimation algorithm together on the chip, which can estimate the SOC in real time. It can accurately identify the SOC of the electric vehicle battery, predict the state of the battery and help drivers determine whether it is enough to ride so as to prevent electric vehicles from power failure when driving and improve the driving safety. In addition, by taking temperature effects into account, the SOC estimation is adaptively adjusted according to temperature changes to ensure that the estimation results at high and low temperatures still have high accuracy.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A Kalman filter-based method for estimation of a state of charge (SOC), comprising:
extracting a cell voltage of a battery pack to calculate a terminal voltage, and matching the terminal voltage in a preset lookup table to obtain an initial value of the SOC;
calculating an initial capacity of the battery pack based on the initial value of the SOC, and calculating a state value of the SOC and an observed value of the SOC in an interval period based on the initial capacity; and
calculating a Kalman gain based on the state value of the SOC and the observed value of the SOC, and updating an estimated value of the SOC based on the Kalman gain, wherein the Kalman gain is calculated through an error covariance between the observed value of the SOC and the actual value of the SOC and an error covariance between the state value of the SOC and the actual value of the SOC in the formula of:
Kₖ=(Pₖ₋₁+Q)/(Pₖ₋₁+Q+R),
wherein Pₖ₋₁ is an error variance between the estimated value of the SOC and the actual value of the SOC at the last moment, Kₖ is the Kalman gain, Q is the error covariance between the state value of the SOC and the actual value of the SOC, and R is the error covariance between the observed value of the SOC and the actual value of the SOC.

2. The Kalman filter-based method of claim 1, wherein the step of extracting the cell voltage of the battery pack to calculate the terminal voltage, and matching the terminal voltage in the preset lookup table to obtain the initial value of the SOC comprises:
identifying a present state of charging or discharging of the battery pack based on a detected current,
wherein, when the battery pack is in the charging state, extracting a first voltage as the cell voltage of the battery pack; and calculating the terminal voltage based on the first voltage, and comparing the terminal voltage with the charging voltage in the lookup table to obtain the corresponding initial value of the SOC.

3. The Kalman filter-based method of claim 2, wherein, when the battery pack is in the discharging state, extracting a second voltage as the cell voltage of the battery pack; and calculating the terminal voltage based on the second voltage, and comparing the terminal voltage with the discharge voltage in the lookup table to obtain the corresponding initial value of the SOC.

4. The Kalman filter-based method of claim 1, wherein the step of calculating the initial capacity of the battery pack based on the initial value of the SOC, and calculating the state value of the SOC and the observed value of the SOC in the interval period based on the initial capacity comprises:
calculating the initial capacity of the battery pack in combination with a rated capacity of the battery pack and a present temperature of the battery pack;
extracting a change value of the initial capacity within the interval period, and calculating the state value of the SOC in combination with the rated capacity and the temperature; and
extracting the cell voltage and current at the present moment within the interval period to obtain a second equivalent resistance, and matching in the look-up table to obtain the observed value of the SOC.

5. The Kalman filter-based method of claim 1, wherein the lookup table is generated by
extracting a charge voltage and a charge current when an electric vehicle is in its first charge, and a discharge voltage and a discharge current when the electric vehicle is its first discharge;
obtaining a first equivalent resistance based on the charging voltage, the discharging voltage, the charging current, and the discharging current; and
generating the lookup table by using the first equivalent resistance, the charge voltage and the discharge voltage as table elements.

6. The Kalman filter-based method of claim 1, further comprising:
updating the Kalman gain in every interval period.

7. The Kalman filter-based method of claim 1, further comprising:
updating the lookup table based on the updated estimated value of the SOC.

8. A system for estimation of a state of charge (SOC) based on a Kalman filter, comprising:
an extraction module, configured to extract a cell voltage of a battery pack to calculate a terminal voltage, and match the terminal voltage in a preset lookup table to obtain an initial value of the SOC;
a calculation module, configured to calculate an initial capacity of the battery pack based on the initial value of the SOC, and calculate a state value of the SOC and an observed value of the SOC in an interval period based on the initial capacity; and
an updating module, configured to calculate a Kalman gain based on the state value of the SOC and the observed value of the SOC, and update an estimated value of the SOC based on the Kalman gain, wherein the Kalman gain is calculated through an error covariance between the observed value of the SOC and the actual value of the SOC and an error covariance between the state value of the SOC and the actual value of the SOC in the formula of:
Kₖ=(Pₖ₋₁+Q)/(Pₖ₋₁+Q+R),
wherein Pₖ₋₁ is an error variance between the estimated value of the SOC and the actual value of the SOC at the last moment, Kₖ is the Kalman gain, Q is the error covariance between the state value of the SOC and the actual value of the SOC, and R is the error covariance between the observed value of the SOC and the actual value of the SOC.

9. A non-transitory tangible computer-readable storage medium storing a computer program which, when executed by one or more processors, carries out the method the program is executed by a processor, the Kalman filter-based method for the SOC estimation of claim 1.

10. An electronic device, comprising:
a processor and a memory; wherein the memory is used to store a computer program, and the processor is used to execute the computer program stored in the memory to cause the electronic device to execute the Kalman filter-based method for the SOC estimation of claim 1.
